(19) United States
(12) Patent Application Publication
(10) Pub. No.: US 2011/0073886 A1
(43) Pub. Date: Mar. 31, 2011

(54) LED multi-side light source bracket

(76) Inventor: Han-Ming Lee, Hsin Chu City (TW)

(21) Appl. No.: 12/586,670

(22) Filed: Sep. 28, 2009

(51) Int. Cl. H01L 33/00

(52) U.S. Cl. 257/91; 257/88; 257/E33.058

(57) ABSTRACT

The present invention relates to a LED multi-side light source bracket, in particular to the bracket design that extends in the rectangular shape directly above the conducting pin for distribution and fixing of a plurality of chips before, after and above the rectangular block, wherein the chips are bridged to another conducting pin on the side through a plurality of conducting wires to be integrated with the resin or silicon lamp housing, the rectangular block support can be bent into the [symbol] shape to double the areas over which chips can be fixed and enable a single LED to create multi-side uniform light source.

### BACKGROUND OF THE INVENTION

Presently, the stray light bulbs generally carry forward the design of two conducting pins bridged with Tungsten wires in the traditional glass shells to create light source. With innovation of the electronic industry and growing environmental protection awareness in recent years, they are gradually replaced by a LED lamp, the structure of which is shown in FIG. 6. Chips are provided inside the chip cup installed above one of the conducting pins to create the forward deflected light source. However, due to the restrictions of the focus function in actual applications, there is not the stray effect. Hence, the structure of the LED lamp needs to be improved to be diversified and practical.

### SUMMARY OF THE INVENTION

The primary purpose of the present invention is to provide a LED multi-face light source bracket and in particular to the bracket design that extends in the rectangular shape directly above one conducting pin for distribution and fixing of a plurality of chips before, after and above the rectangular block to enable a single LED to create multi-side uniform light source.

The secondary purpose of the present invention is to provide a LED multi-side light source bracket, wherein a plurality of conducting wires are bridged to the chips through another conducting pin and integrated with the resin or silicon lamp housing.

Another purpose of the present invention is to provide a LED multi-side light source bracket, wherein the rectangular block support may be bent into the [symbol] shape to double the areas over which chips can be fixed.

### BRIEF DESCRIPTION OF THE DRAWINGS

FIG. 1 is a 3D diagram of the present invention.

FIG. 2 is a schematic diagram of the components of the present invention.

FIG. 3 is a cross-section 3D diagram of the present invention.

FIG. 4 is a 3D schematic of the lighting chip of the present invention.

FIG. 5 is a schematic of another embodiment of the bracket of the present invention.

FIG. 6 is a schematic of the traditional structure.

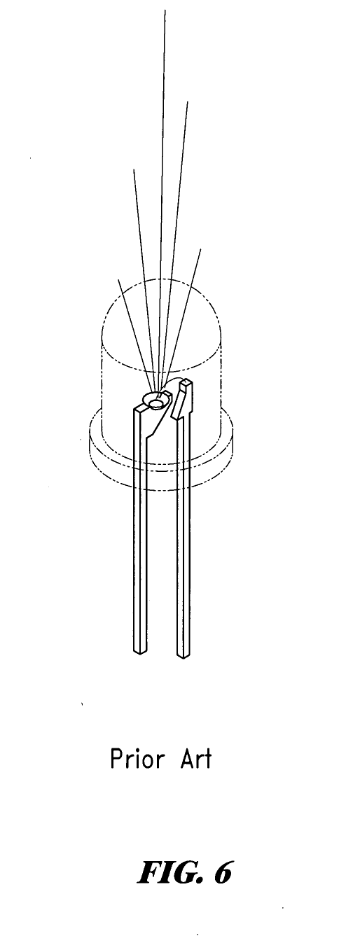

### DETAILED DESCRIPTION OF THE PREFERRED EMBODIMENT

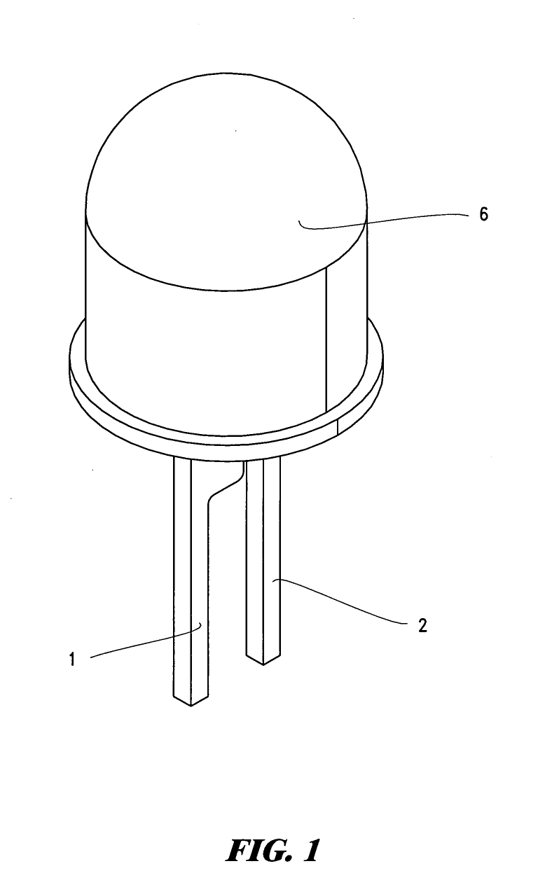

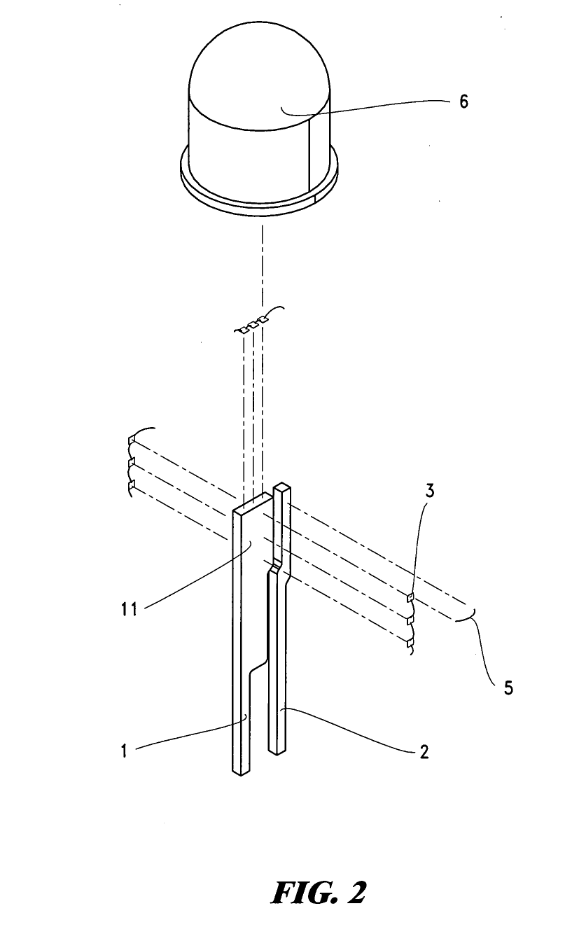

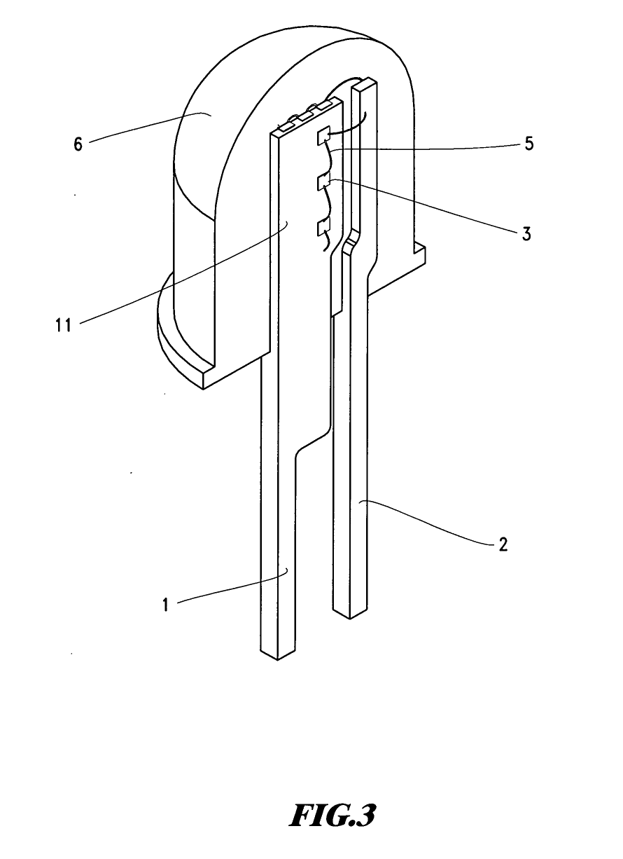

Please refer to FIGS. 1 through FIGS. 3. The present invention relates to a LED multi-side light source bracket, comprising conducting pins 1 and 2, a plurality of chips 3, a plurality of conducting wires 5 and silicon lamp housing 6; the conducting pin 1 is a conducting pin above which the bracket design of rectangular block 11 directly extends; the conducting pin 2 is another conducting pin located outside the conducting pin 1; a plurality of chips 3 are lighting semi-conductor chips for distribution and fixing before, after and above the rectangular block 11; a plurality of conducting wires 5 are made of conducting materials with one end connected to the chip 3 and the other end connected to conducting pin 2; the silicon lamp housing 6 is made of resin or silicon light-transmitting material for integration with conducting pins 1 and 2, chip 3 and conducting wire 5.

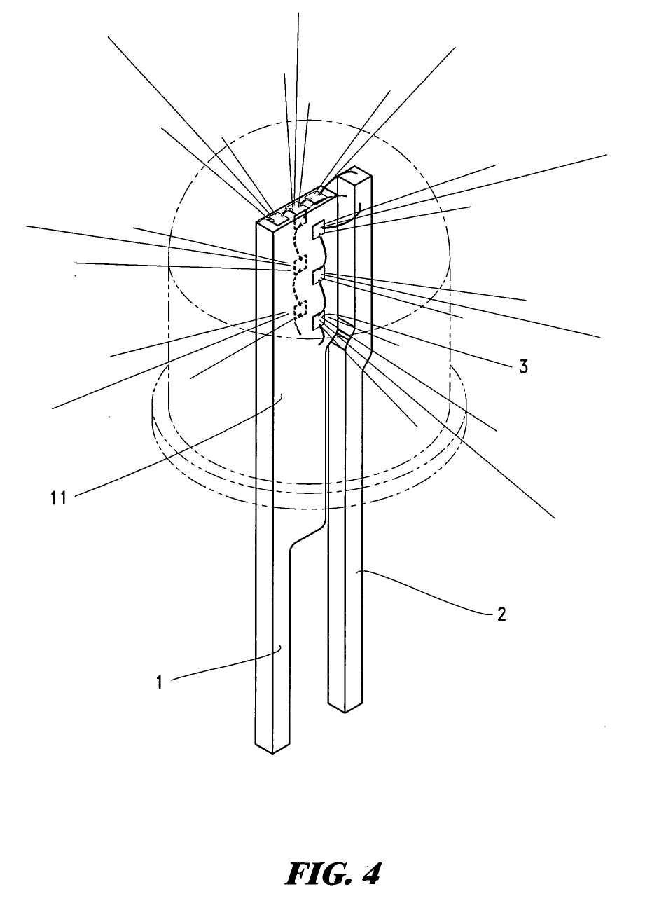

Please refer to FIG. 4 for one embodiment of this invention. The bracket design of rectangular block 11 above the conducting pin 1 is provided for distribution and fixing a plurality of chips 3 before, after and above the block and the chips 3 are bridged with another conducting pin 2 through a plurality of conducting wires 5 so that the silicon lamp housing 6 is integrated with conducting pins 1 and 2, chips 3 and conducting wires 5 to enable a single LED to create LED multi-side uniform light source.

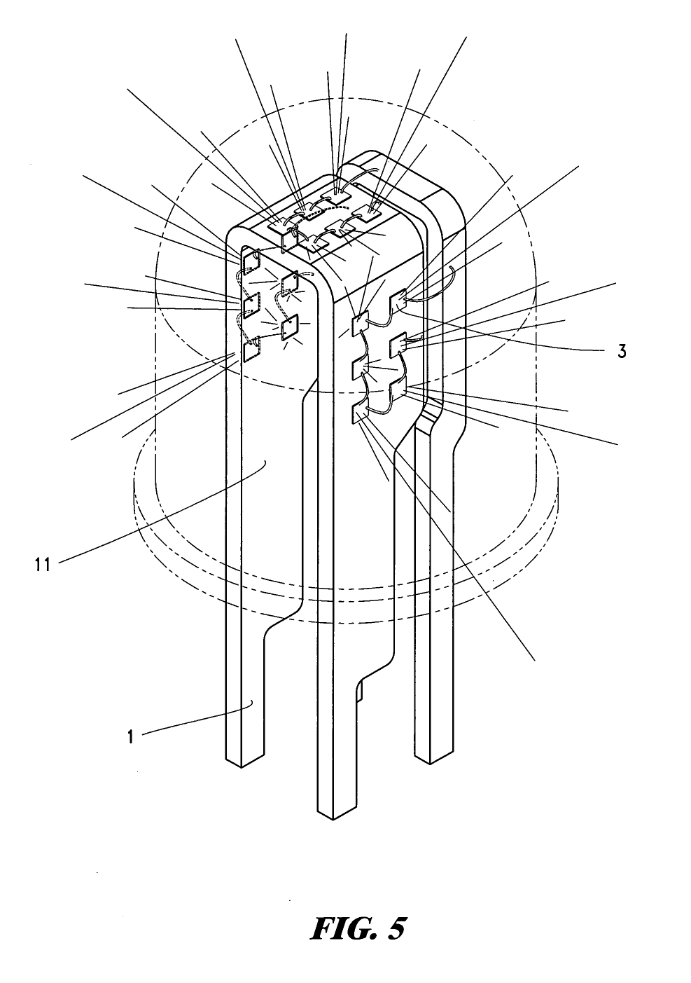

Please refer to FIG. 5 for another embodiment of this invention. The bracket of rectangular block 11 of this invention can be bent into the [symbol] shape to double the areas over which the chips can be fixed.

I claim:

1. LED multi-side light source bracket, comprising two conducting pins, a plurality of chips, a plurality of conducting wires and silicon lamp housing, the main improvements including: the bracket design of the rectangular block directly extends over a conducting pin for distribution and fixing of a plurality of chips before, after and above the rectangular block and the chips are bridged to another conducting pin on the side by a plurality of conducting wires to be integrated with the resin or silicon lamp housing to enable a single LED to create LED multi-side uniform light source.

2. The LED multi-side light source bracket according to claim 1, wherein the rectangular block can be extended and bent into the [symbol] shape to double the areas over which the chips can be fixed.
